(19) United States
(12) Patent Application Publication
(10) Pub. No.: US 2024/0404940 A1
(43) Pub. Date: Dec. 5, 2024

(54) BIPOLAR TRANSISTOR

(71) Applicant: STMicroelectronics International N.V., Geneva (CH)

(72) Inventor: Pascal CHEVALIER, Chapareillan (FR)

(73) Assignee: STMicroelectronics International N.V., Geneva (CH)

(21) Appl. No.: 18/678,025

(22) Filed: May 30, 2024

(30) Foreign Application Priority Data
May 31, 2023 (FR) 2305435

(51) Int. Cl. H01L 23/498; H01L 29/08; H01L 29/10; H01L 29/66; H01L 29/735

(52) U.S. Cl. CPC H01L 23/49844; H01L 29/0808; H01L 29/1008; H01L 29/6656; H01L 29/735

(57) ABSTRACT

A device includes a bipolar transistor. The bipolar transistor includes: a collector region, a base region, and an emitter region. A first metallization is in contact with the emitter region, a second metallization is in contact with the base region, and a third metallization is in contact with the collector region. A first connection element is coupled to the first metallization and has dimensions, in a plane of the interface between the first metallization and the connection element, greater than dimensions of the first metallization. A second connection element is coupled to the second metallization and passes through spacers, which at least partially cover the second metallization, surrounding the emitter region. A third connection element is coupled to the third metallization and passes through spacers, which at least partially cover the third metallization, surrounding the base region.

### PRIORITY CLAIM

This application claims the priority benefit of French Application for Patent No. 2305435, filed on May 31, 2023, the content of which is hereby incorporated by reference in its entirety to the maximum extent allowable by law.

### TECHNICAL FIELD

The present disclosure generally concerns electronic devices and, in particular, electronic devices comprising bipolar transistors and their manufacturing methods.

### BACKGROUND

A bipolar transistor is a semiconductor-based electronic device of the family of transistors. Its operating principle is generally based on two PN junctions, one forward and the other in reverse.

There is a need in the art to overcome all or part of the disadvantages of known electronic devices comprising bipolar transistors.

### SUMMARY

In an embodiment, a device comprises a bipolar transistor, wherein the bipolar transistor comprises: a collector region, a base region, and an emitter region; a first metallization in contact with the emitter region; and a connection element coupled to the first metallization and having dimensions, in a plane of the interface between the first metallization and the connection element, greater than dimensions of the first metallization.

In another embodiment, a method of manufacturing a device comprising a bipolar transistor comprises: forming a collector region, a base region, and an emitter region; forming a first metallization in contact with the emitter region; and forming a connection element in contact with the first metallization and having dimensions, in a plane of the interface between the first metallization and the connection element, greater than dimensions of the first metallization.

According to an embodiment, a distance between each wall and an opposite wall of the connection element is greater than a distance between opposite walls of the first metallization in a same direction.

According to an embodiment, an upper surface of the first metallization is entirely in contact with the connection element.

According to an embodiment, the bipolar transistor further comprises: a second metallization in contact with the base region; and a first spacer partially covering the first metallization.

According to an embodiment, the first spacer surrounds the emitter region.

According to an embodiment, the transistor is covered with a first insulating layer through which the connection element crosses.

According to an embodiment, the device comprises conductive contacts that cross through the first layer so as to contact the second metallization.

According to an embodiment, at least one conductive contact crosses through the first spacer.

According to an embodiment, the material of the first insulating layer is selectively etchable over the material of the first spacer.

According to an embodiment, the transistor comprises second spacers at least partially covered with the first spacers.

According to an embodiment, the second spacers are formed before the forming of the second metallization.

According to an embodiment, the first spacer is formed after the forming of the second metallization.

According to an embodiment, the transistor comprises a third metallization in contact with the collector region, and third spacers partially covering the third metallization.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an example of a device comprising a bipolar transistor;

FIG. 2 shows an embodiment of a bipolar transistor;

FIG. 3 shows a step of a method of manufacturing the embodiment of FIG. 2;

FIG. 4 shows another step of the method of manufacturing the embodiment of FIG. 2; and

FIG. 5 shows another step of the method of manufacturing the embodiment of FIG. 2.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

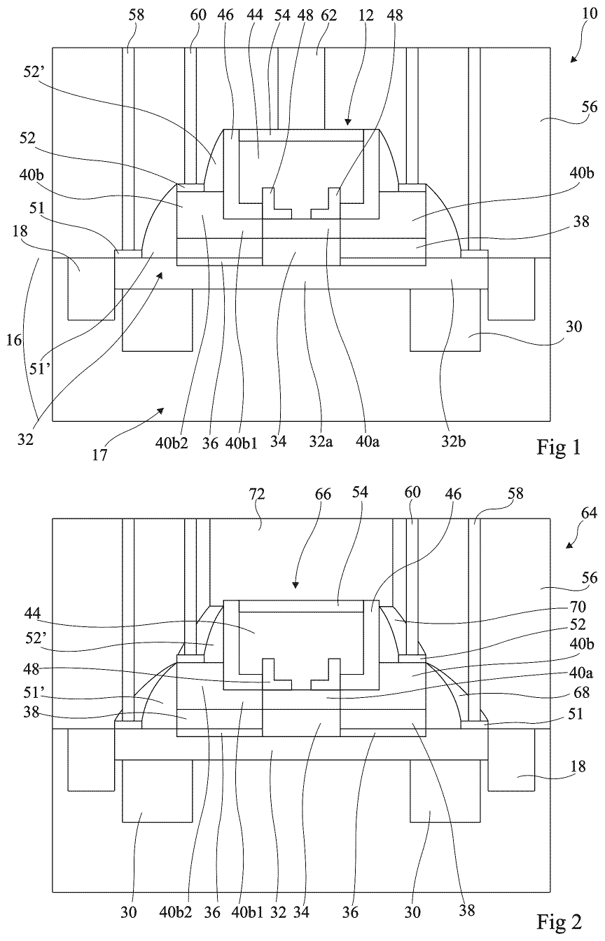

FIG. 1 shows a more specific example of a device 10 comprising a bipolar transistor 12.

Transistor 12 is formed inside and on top of a substrate 16. Substrate 16 is a semiconductor substrate, for example made of silicon. Substrate 16 comprises a region 17 having transistor 12 located therein.

The region (or portion) 17 of substrate 16 is separated from other regions for example comprising other components, for example other transistors, by insulating trenches 18, for example trenches forming a so-called deep trench insulation. Trenches 18 are, for example, made of silicon oxide.

Transistor 12 comprises collector regions 30, 32, and 34. Regions 30 are located in substrate 16, and more precisely in region 17. Regions 30 are, for example, doped with a first doping type, for example type N. Transistor 12 comprises, for example, two regions 30 extending in parallel directions. Regions 30 are, for example, separated from each other by a non-doped portion of the substrate.

Alternatively, transistor 12 comprises a single region 30 forming a ring in region 17. Single portion 30 then surrounds a preferably non-doped region of the substrate.

Region 32 is located on regions 30. In other words, a lower surface of region 32 is in contact with upper surfaces of regions 30. Region 32 electrically couples regions 30. Region 32 is, for example, doped with the same conductivity type as region 30. Region 32 preferably comprises a central portion 32a and a peripheral portion 32b. The peripheral portion 32b, for example, forms a ring surrounding central portion 32a.

Central portion 32a, for example, has a height (i.e., thickness) smaller than the height of peripheral portion 32b. Portions 32a and 32b, for example, have a planar lower surface. The lower surfaces of portions 32a and 32b are thus, for example, coplanar. The upper surface of peripheral portion 32b is, for example, coplanar with the upper surface of trenches 18.

Region 34 is in contact with region 32 (at the central portion 32a). Region 34 extends from the upper surface of central portion 32a. For example, the height of region 34 is greater than the height difference between portions 32a and 32b. Thus, the upper surface of region 34 is, for example, at a level higher than the level of the upper surface of portion 32b.

Preferably, regions 30 have a substantially constant dopant concentration. Preferably, region 32 has a substantially constant dopant concentration. Regions 30 and 32 preferably have a dopant concentration higher than the dopant concentration of region 34, for example at least one hundred times higher, for example at least one thousand times higher. For example, the dopant concentration of regions 30 and 32 is, for example, higher than 10¹⁸ atoms/cm², for example higher than 10²¹ atoms/cm². For example, the dopant concentration in region 34 is lower than 10¹⁶ atoms/cm², for example in the range from 10¹⁴ atoms/cm² to 10¹⁶ atoms/cm².

Transistor 12 comprises, for example, a region 36 surrounding a lower portion of region 34. Region 36 extends, for example, from the upper surface of central portion 32a to the level of the upper surface of portion 32b. Region 36 preferably extends from the lateral surface of region 34 to the lateral wall of portion 32b. Region 36 is, for example, made of the same material as substrate 14. Region 36 is, for example, non-doped. Alternatively, region 36 is, for example, made of an insulating material.

The upper portion of region 34 is surrounded with an insulating region 38. Insulating region 38 is located on the upper surface of region 36. Region 38, for example, entirely covers the upper surface of region 36. Region 38, for example, only covers region 36. The upper surface of region 38 is, for example, planar. The upper surface of region 38 is preferably coplanar with the upper surface of region 34.

Transistor 12 comprises a base 40. Base 40 comprises a central portion 40a and a peripheral portion 40b. Central portion 40a is laterally surrounded with peripheral portion 40b. Peripheral portion 40b thus forms a ring around central portion 40a.

Central portion extends from region 34. In other words, the lower surface of central portion 40a is in contact with the upper surface of region 34. The lateral surfaces of central portion 40a are in contact with peripheral portion 40b. Central portion 40a and peripheral portion 40b are thus electrically coupled.

Peripheral portion 40b covers, preferably entirely, preferably only, region 38, more precisely the upper surface of region 38. Peripheral portion 40b comprises, for example, a (sub) portion 40b1 in contact with the lateral surface of central portion 40a. Portion 40b1, for example, has a height substantially equal to the height of portion 40a. Peripheral portion 40b, for example, further comprises a (sub) portion 40b2 having a height greater than the height of portion 40b1. Portion 40b2 extends around portion 40b1. Portion 40b1 is separated from central portion 40a by portion 40b1.

Base 40 preferably entirely extends over layer 38 and region 34. Layer 38 and region 34 are entirely covered with base 40. Preferably, the lateral surfaces of portion 40b and of layer 38 are coplanar.

Base 40 is made of a semiconductor material, for example made of silicon. The doping type of base 40 is the type opposite to the doping of the collector, for example type P.

Transistor 12 further comprises an emitter region 44. Emitter region 44 rests on base 40. More precisely, emitter region 44 extends above at least part of central portion 40a and, for example, above part of peripheral portion 40b. Thus, part of peripheral portion 40b is not covered with emitter region 44. Part of base 40 is thus not covered with the emitter region.

Emitter region 44 is laterally surrounded with an insulating region 46. Insulating region 46 thus covers, for example entirely, the lateral surfaces of emitter region 44. Insulating region 46, for example, also covers a lower portion of emitter region 44. The lower surface of the emitter region is entirely covered with insulating region 46 and an insulating region 48, except for a portion of the lower surface of emitter region 44 in contact with central portion 40a. Said portion of the lower surface is, for example, surrounded by region 48, for example having an L-shaped profile. Region 46, for example, surrounds region 48. In other words, region 48, for example, comprises a horizontal portion covering a peripheral portion of the upper surface of portion 40a and a vertical portion extending from the upper surface of portion 40a. The lateral wall of the vertical portion is, for example, at least partially in contact with a lateral surface of region 46.

Emitter region 44 is made of a semiconductor material, for example made of silicon. The doping type of emitter region 44 is the type opposite to the doping of the base, that is, the same type as the collector, for example type N.

Transistor 12 further comprises metallizations 51, 52, 54 respectively resting on portions of the collector, of the base, and of the emitter. Metallizations 51, 52, 54 are more precisely respectively located on the upper surface of portion 32b, on the upper surface of part of portion 40b, and on the upper surface of emitter 44. Metallizations 51 are separated from region 38 and from portion 40b by spacers 51′. Similarly, metallizations 52 are separated from region 56 by spacers 52′. The metallizations may, for example, comprise a silicide.

Device 10 further comprises an insulating layer 56 covering, for example, transistor 12. Layer 56 has a thickness greater than the distance between the upper surface of substrate 16 and the upper surface of metallization 54. Transistor 12 is thus entirely covered with layer 56.

Device 10 comprises conductive contacts 58, 60, 62 crossing layer 56 to reach, respectively, metallizations 51, 52, 54.

The decrease of the dimensions of emitter region 44 allows the decrease of the extrinsic base resistance. It is however desired to decrease the extrinsic base resistance, without modifying the operating frequency of the transistor.

FIG. 2 shows an embodiment of a device 64 comprising a bipolar transistor 66.

Device 64 and transistor 66 comprise the elements previously described in relation with FIG. 1. Thus, transistor 66 comprises collector regions 30, 32, 34, base region 40, and emitter region 44. Transistor 66 comprises, for example, semiconductor region 36 and insulating regions 38, 46, and 48. Transistor 66 comprises spacers 51′, 52′ and metallizations 51, 52, and 54. Device 64 comprises walls 18 and layer 56. Device 64 further comprises contacts 58 and 60 such as previously described.

More generally, transistor 66 may have characteristics different from those of the transistor described in relation with FIG. 1.

Generally, a bipolar transistor usually comprises a collector region, corresponding to regions 30, 32, 34 in FIG. 2, located, for example, in a semiconductor substrate, corresponding to substrate 16. The collector region preferably comprises portions, corresponding to the regions 32b of FIG. 1, flush with the upper surface of the substrate.

The bipolar transistor further comprises a base region, corresponding to region 40 in FIG. 2, located on the collector region. Preferably, the base region has horizontal dimensions smaller than the horizontal dimensions of the collector region. Thus, a portion of the collector region, corresponding to the portion 32b of FIG. 1, flush with the upper surface of the substrate, is preferably not covered with the base region.

Similarly, the transistor comprises an emitter region, corresponding to the region 44 of FIG. 2, located on the base region. Preferably, the emitter region has horizontal dimensions smaller than the horizontal dimensions of the base region. Thus, a portion of the base region, corresponding to the portion 40b2 of FIG. 2, is preferably not covered with the emitter region.

The bipolar transistor comprises, for example, metallizations, corresponding to the metallization 51, 52 of FIG. 2, on the portions of the collector and base regions not covered with, respectively, the base and emitter regions. The bipolar transistor, for example, comprises vias, or contacts, reaching said metallizations.

Said metallizations are preferably separated from the base or emitter regions by spacers made of electrically-insulating materials.

According to an embodiment, device 64 differs from the device 10 of FIG. 1, and from a usual bipolar transistor, in that transistor 66 comprises spacers 68 and 70. Spacers 68 are located on and covering spacers 51′ and on and covering metallizations 51. Preferably, spacers 51F are entirely covered with spacers 68. Contacts 58 cross through, in addition to layer 56, spacers 68 to reach metallizations 51. Spacers 70 are located on and covering spacers 52′ and on and covering metallizations 52. Preferably, spacers 52′ are entirely covered by spacers 70. Contacts 60 may cross through, in addition to layer 56, spacers 70 to reach metallizations 52.

Device 64 further differs from the device 10 of FIG. 1 in that device 64 comprises no contact 62 but comprises a connection element, or contact, 72. The dimensions of connection element 72, in particular the horizontal dimensions, are such that the upper surface of metallization 54 is entirely in contact with element 72. In other words, the horizontal dimensions of element 72 are greater than the horizontal dimensions of metallization 54. Preferably, the horizontal dimensions of connection element 72 are such that the lower surface of element 72 is in contact with at least a portion of the upper surface of layer 46, preferably the entire upper surface of layer 46. In other words, the distance between each wall and the opposite wall of connection element 72 is greater than the distance between the opposite walls of metallization 54 in the same direction. The horizontal dimensions of connection element 72 are such that the lower surface of element 72 is in contact with an upper portion of the lateral walls of element 46. Thus, a portion of the height of metallization 54 is, for example, surrounded by the connection element.

The interface between element 72 and metallization 54 has the maximum dimensions, that is, corresponds to the entire upper surface of metallization 54. The emitter resistance is thus lower than the emitter resistance of the structure of FIG. 1.

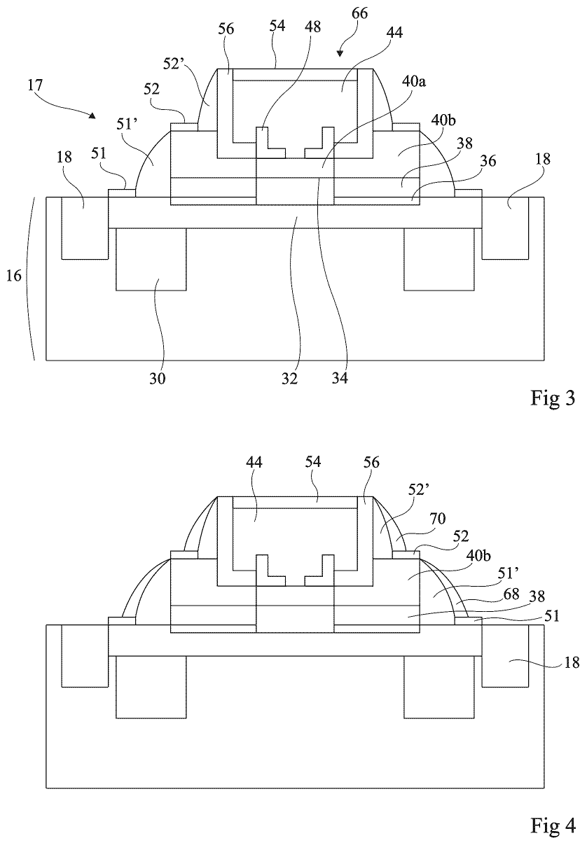

FIG. 3 shows a device resulting from a step of a method of manufacturing the embodiment of FIG. 2.

During this step, the bipolar transistor is formed. This step thus comprises the forming of the collector, of the base, and of the emitter. This step further comprises the forming of metallizations 51, 52, 54 and of spacers 51′, 52′. In the example of FIG. 3, this step for example more precisely comprises: the forming of insulating walls 18 around region 17 of substrate 16; the forming, by doping of the substrate, of regions 30 and 32 of the substrate; the forming of a stack of layers over the entire structure, the stack comprising at least a lower insulating layer, an intermediate insulating layer, and an upper insulating layer, for example made of an insulating material different from the material of the intermediate layer; the forming of a cavity crossing the stack at the location of region 34 and of portion 40a, to reach region 32; the forming of region 34 and of portion 40a in the cavity; the forming of elements 48; the forming of a layer made of the material of the emitter and the etching of said layer and of the upper layer of the stack to form the emitter; the forming of layer 56; the forming of portions 40b, for example by epitaxial growth; the forming of spacers 51′, 52′; and the forming of metallizations 51, 52, 54.

The step of FIG. 3 may, for example, by replaced with another method of manufacturing a bipolar transistor comprising the forming of the collector, of the base, and of the emitter and the forming of metallizations 51, 52, 54 and of spacers 51′, 51′.

FIG. 4 shows a device resulting from another step of the method of manufacturing the embodiment of FIG. 2.

During this other step, spacers 68 and 70 are formed. More precisely, a layer made of the material of spacers 68 and 70 is formed over the entire structure. In particular, said layer covers metallizations 51, 52 and spacers 51′ and 52′.

The step of FIG. 4 further comprises a step of anisotropic etching of said layer made of the material of spacers 68 and 70. The layer is thus etched so as to be entirely removed, except for spacers 68 and 70. Spacers 68, 70 cover in particular metallizations 51 and 52 and spacers 51′, 52′. Spacers 68, 70 preferably entirely cover spacers 51′ and 52′ and at least partially cover metallizations 51, 52. Spacers 68 may partially cover metallizations 51 as shown in FIG. 4 (or completely cover as shown in FIG. 2). More precisely, spacers 68 cover at least the portion of metallizations 51 closest to spacers 51′. For example, spacers 68 cover at least 5% of metallizations 51. Similarly, spacers 70 may partially cover metallizations 52 as shown in FIG. 4 (or completely cover as shown in FIG. 2). More precisely, spacers 70 cover at least the portion of metallizations 52 closest to spacers 52′. For example, spacers 70 cover at least 5% of metallizations 52.

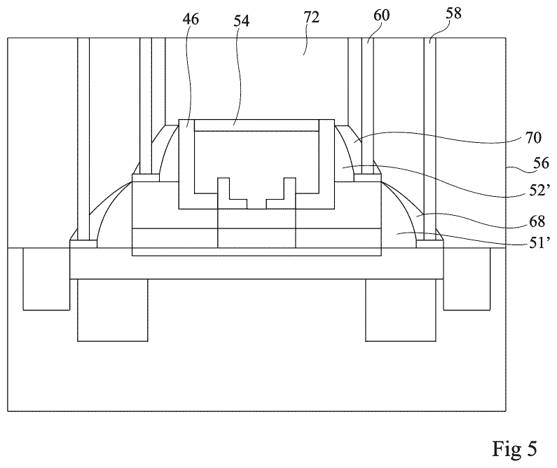

FIG. 5 shows a device resulting from another step of the method of manufacturing the embodiment of FIG. 2.

During this other step, layer 56 is formed over the entire structure. Thus, layer 56 has a thickness greater than the distance between the upper surface of substrate 16 and the upper surface of metallization 54. The transistor is thus entirely covered by layer 56.

Layer 56 and spacers 68, 70 are preferably made of different materials. For example, layer 56 is made of a material selectively etchable over the material of spacers 68, 70.

The step of FIG. 5 further comprises the forming of contacts 58, 60 and of connection element 72. The forming of contacts 58 comprises the forming of cavities crossing through layer 56 and through spacers 51′ and 68 to reach metallization 51. The forming of contacts 60 comprises the forming of cavities crossing through layer 56 and spacers 52′ and 70 to reach metallization 52. The forming of element 72 comprises the forming of a cavity crossing through layer 56 to reach metallization 54.

The forming of the cavities corresponding to contacts 58, 60 comprises, for example, a plurality of etch steps corresponding to the materials of layer 56 and of spacers 21′, 52′, 68, 70. The forming of the cavity corresponding to connection element 72, for example, comprises a single selective etching of the material of layer 56 over the material of spacers 70. In other words, the material of layer 56 is etched at least twice, preferably at least five times, faster than the material of spacers 70. Thus, spacers 70 are, for example, not etched during the forming of the cavity corresponding to element 72 or are etched along a lower height, for example along a height smaller than half the distance between the upper surface of metallization 54 and the upper surface of metallization 52.

For example, the forming of contacts 58, 60 and the forming of element 72 are not performed simultaneously. Thus, the cavities corresponding to contacts 58, 60 are formed before the forming of the cavity corresponding to element 72, the cavities being simultaneously filled. Alternatively, the cavity corresponding to element 72 is formed and filled by element 72 before the forming of the cavity corresponding to contacts 58, 60.

An advantage of the described embodiments is that it is possible to protect metallizations 52 from element 72.

Another advantage of the described embodiments is that it is possible to decrease the width of the emitter without risking connecting the base and the emitter. It is thus possible to decrease the extrinsic base resistance.

Another advantage of the described embodiments is that it is possible to bring metallizations 51 closer to the emitter, by decreasing the width of spacers 52′, and thus to decrease the intrinsic base resistance.

Another advantage of the described embodiments is that problems of alignment of the connection element cause less risks of disturbance of the transistor operation.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A device comprising a bipolar transistor, the bipolar transistor comprising:
a collector region, a base region, and an emitter region;
a first metallization at an upper surface of the emitter region; and
a connection element coupled to the first metallization and having dimensions, in a plane of an interface between the first metallization and the connection element, greater than dimensions of the first metallization.

2. The device according to claim 1, wherein a distance between opposite walls of the connection element is greater than a distance between opposite walls of the first metallization in a same direction.

3. The device according to claim 1, wherein an upper surface of the first metallization is entirely covered by, and in contact with, the connection element.

4. The device according to claim 3, wherein the transistor is covered with a first insulating layer, and wherein the connection element crosses through the first insulating layer to reach the first metallization.

5. The device according to claim 1, wherein the bipolar transistor further comprises:
a second metallization at an upper surface of the base region; and
a first spacer that at least partially covers the second metallization.

6. The device according to claim 5, wherein the first spacer surrounds the emitter region.

7. The device according to claim 5, wherein the transistor is covered with a first insulating layer, and wherein the device comprises a conductive contact crossing through the first insulating layer to reach the second metallization.

8. The device according to claim 7, wherein the conductive contact further crosses through the first spacer.

9. The device according to claim 8, wherein a material of the first insulating layer is selectively etchable over a material of the first spacer.

10. The device according to claim 8, wherein the transistor comprises a second spacer that is at least partially covered by the first spacer, and wherein said second spacer does not cover the second metallization.

11. The device according to claim 1, wherein the bipolar transistor further comprises:
a third metallization at an upper surface of the collector region; and
a third spacer that at least partially covers the third metallization.

12. The device according to claim 11, wherein the third spacer surrounds the base region.

13. The device according to claim 11, wherein the transistor is covered with a first insulating layer, and wherein the device comprises a conductive contact crossing through the first insulating layer to reach the third metallization.

14. The device according to claim 13, wherein the conductive contact further crosses through the third spacer.

15. The device according to claim 14, wherein a material of the first insulating layer is selectively etchable over a material of the third spacer.

16. The device according to claim 14, wherein the transistor comprises a fourth spacer that is at least partially covered by the third spacer, and wherein said fourth spacer does not cover the third metallization.

17. A device comprising a bipolar transistor, the bipolar transistor comprising:
a collector region, a base region, and an emitter region;
a first metallization at an upper surface of the emitter region; and
a connection element coupled to the first metallization and having dimensions, in a plane of an interface between the first metallization and the connection element, greater than dimensions of the first metallization;
a second metallization at an upper surface of the base region;
a first spacer that at least partially covers the second metallization;
wherein the transistor is covered with a first insulating layer;
wherein the connection element crosses through the first insulating layer to reach the first metallization;
wherein the device comprises a conductive contact crossing through the first insulating layer to reach the second metallization; and
wherein the conductive contact further crosses through the first spacer.

18. The device according to claim 17, wherein an upper surface of the first metallization is entirely covered by, and in contact with, the connection element.

19. The device according to claim 17, wherein the first spacer surrounds the emitter region.

20. The device according to claim 17, wherein the transistor comprises a second spacer that is at least partially covered by the first spacer, and wherein said second spacer does not cover the second metallization.
